(19) United States
(12) Patent Application Publication
(10) Pub. No.: US 2022/0410828 A1
(43) Pub. Date: Dec. 29, 2022

(54) MULTIPLEX CONTROLLER ASSEMBLY

(71) Applicant: Dometic Sweden AB, Solna (SE)

(72) Inventors: Eric Joseph Schuh, Stevensville, MI (US); Paul Argue, Saint Joseph, MI (US); Clayton Hendry Meyers, Paw Paw, MI (US)

(21) Appl. No.: 17/438,032

(22) PCT Filed: Mar. 10, 2020
(86) PCT No.: PCT/IB2020/052065

§ 371 Date: Sep. 10, 2021

Related U.S. Application Data
(60) Provisional application No. 62/816,534, filed on Mar. 11, 2019.

(51) Int. Cl. B60R 16/03; H05K 5/00; H05K 5/02

(52) U.S. Cl. CPC B60R 16/0315; H05K 5/0021; H05K 5/0221; H05K 5/0018

(57) ABSTRACT

Present embodiments relate to a multiplex controller assembly. More specifically, but without limitation, present embodiments relate to a controller which may be multiplexed by addition of one or more controller assemblies in order to provide easier control of multiple systems within a recreational vehicle (RV).

### CLAIM TO PRIORITY

This 35 U.S.C. § 371 National Stage Patent Application claims priority to PCT Patent Application No. PCT/IB2020/052065, filed Mar. 10, 2020, and titled “Multiplex Controller Assembly” which claims priority to and benefit of U.S. Provisional Patent Application Ser. No. 62/816,534, filed Mar. 11, 2019 and titled “Multiplex Controller Assembly”, all of which is incorporated by reference herein.

### CROSS REFERENCE

Cross-reference is made to U.S. Provisional Patent Application No. 62/816,561, titled “Predictive Analysis System for Recreational Vehicle”, filed on Mar. 11, 2019, and U.S. Design Patent Application No. 29/683,099, titled “Controller,” also filed on Mar. 11, 2019, all of which is expressly incorporated herein by reference.

### BACKGROUND

### 1. Field of the Invention

Present embodiments relate to a multiplex controller assembly. More specifically, but without limitation, present embodiments relate to a controller which may be multiplexed by addition of one or more controller assemblies in order to provide easier control of multiple systems within a recreational vehicle (RV).

### 2. Description of the Related Art

Recreational vehicles (RVs) utilize various systems in order to make camping more enjoyable. For example, RVs may include HVAC systems, awning control, power systems, appliances, and systems for fresh water and waste. This list is not exhaustive and others may be present. Each of these systems requires a separate control, for example, in order to extend or retract an awning, control temperature with air conditioning or heat, control for monitoring fresh water and waste water, and/or other controls for any of the systems existing in the RV. It would be desirable to provide a controller which makes these controls more uniform in function and operation and allows location, if desirable, in groups at different places about the RV, depending on the system desired to be controlled.

In doing this however, it is typical that a single controller would require scrolling through multiple menus in order to provide access to controls for a first system in the RV as opposed to a second system in the RV, and so on. This continual scrolling through multiple screens may become undesirable. Further, it may desirable, to be able to access controls for two differing systems at the same time.

Thus it would be desirable to provide a system which provides a solution for allowing control of multiple systems either at a single time and/or without the need to scroll through multiple menus in order to control one system as opposed to a second system and which provides uniformity of control throughout the RV.

The information included in this Description of Related Art section of the specification, including any references cited herein and any description or discussion thereof, is included for technical reference purposes only and is not to be regarded subject matter by which the scope of the invention is to be bound.

### SUMMARY

The present application discloses one or more of the features recited in the appended claims and/or the following features which alone or in any combination, may comprise patentable subject matter.

According to some embodiments, a multiplex controller assembly, comprises a first controller having: a display, a speaker, a frame having one of a connector or an opening for the connector, a second controller having a second display, a second speaker, and a second frame, which is connectable to the first frame in order to provide the multiplex controller assembly.

According to some optional embodiments, the multiplex controller assembly may further comprise a connector disposed between the first controller and the second controller. The multiplex controller assembly may further comprise at least one electrical connector. The connector may be at least one mechanical connector. The at least one mechanical connector may have a first connector which inhibits motion in one direction. The multiplex controller assembly may further comprise a second connector which inhibits motion in a second direction. The multiplex controller assembly may further comprise a camera on each of the first and second controllers. The first and second controllers may be horizontally aligned or may be vertically aligned. The connector may be a distinct part formed separate of the frame. Alternatively, the connector may be formed integrally with the frame. The first controller may control one system of the RV and the second controller may control a second system.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. All of the above outlined features are to be understood as exemplary only and many more features and objectives of the various embodiments may be gleaned from the disclosure herein. Therefore, no limiting interpretation of this summary is to be understood without further reading of the entire specification, claims and drawings, included herewith. A more extensive presentation of features, details, utilities, and advantages are provided in the following written description of various embodiments, illustrated in the accompanying drawings, and defined in the appended claims.

### BRIEF DESCRIPTION OF THE DRAWINGS

In order that the embodiments may be better understood, embodiments of a multiplex controller assembly will now be described by way of examples. These embodiments are not to limit the scope of the claims as other embodiments of a multiplex controller assembly will become apparent to one having ordinary skill in the art upon reading the instant description. Non-limiting examples of the present embodiments are shown in figures wherein:

FIG. 1 is a perspective view of a recreation vehicle (RV) which shows various illustrative systems which may be controlled;

FIG. 2 is a perspective view of an illustrative embodiment of the multiplex controller assembly;

FIG. 3 is a rear perspective view of the multiplex controller assembly of FIG. 2;

FIG. 4 is a first perspective view of a connector for the multiplex controller assembly;

FIG. 5 is a second perspective view of a connector for the multiplex controller assembly;

FIG. 6 is a rear exploded perspective view of the multiplex controller assembly;

FIG. 7 is a second rear perspective view of the exploded multiplex controller assembly;

FIG. 8 is a schematic view of various control screens accessible with each of the displays of the multiplex controller assembly; and,

FIGS. 8A-8I are the control screens as shown in FIG. 8.

### DETAILED DESCRIPTION

It is to be understood that a multiplex controller assembly is not limited in its application to the details of construction and the arrangement of components set forth in the following description or illustrated in the drawings. The described embodiments are capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings.

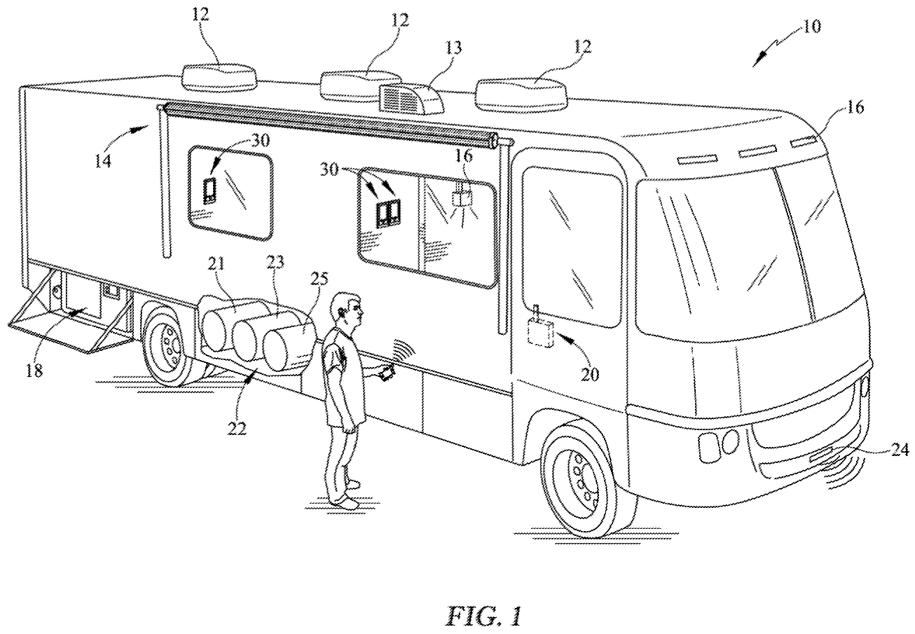

Referring now to FIGS. 1-8I, various embodiments of a multiplex controller assembly are provided. The controller comprises two or more controllers which may be mechanically connected or electrically connected or both in order to provide multiple controls for each of at least two different recreational vehicles (“RV”) systems. The multiplex controller also inhibits the need to scroll through numerous differing screens in order to control a first system and also control a second system. It should be understood that although an RV 10 is shown as a drivable vehicle, the term “RV” is not limited to drivable vehicles. The term “RV” is also meant to include towable structures, sometimes called campers, as well as boats or other marine applications, commercial vehicles, agricultural vehicles, horse trailers, and temporary structures such as those used at sports events, (tailgating), flea markets. Further, the term “RV” may be inclusive of fixed structures such as homes, cabins or commercial structures, all of which may utilize an awning assembly. All of these structures are considered to be usable with the controller assembly of the present embodiments.

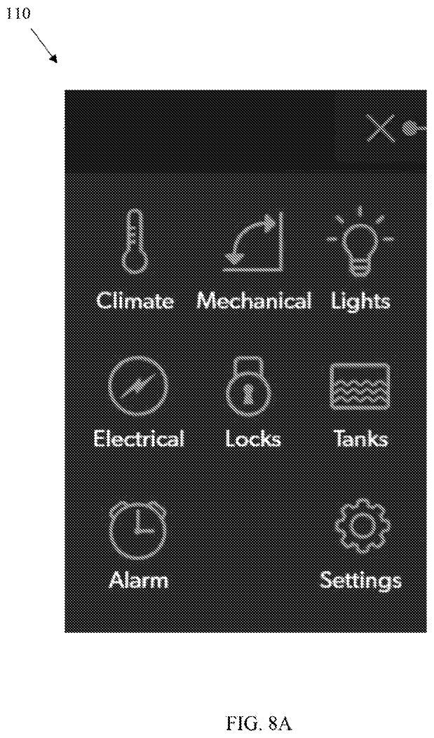

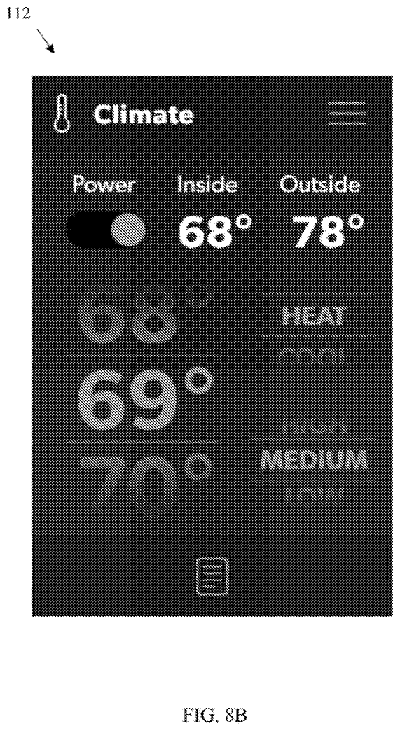

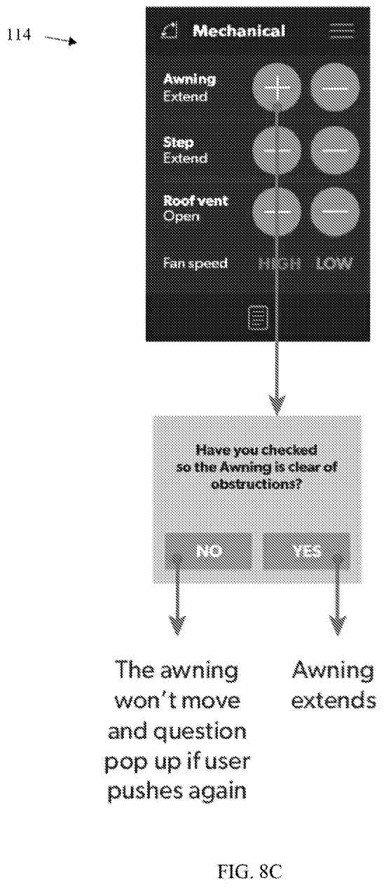

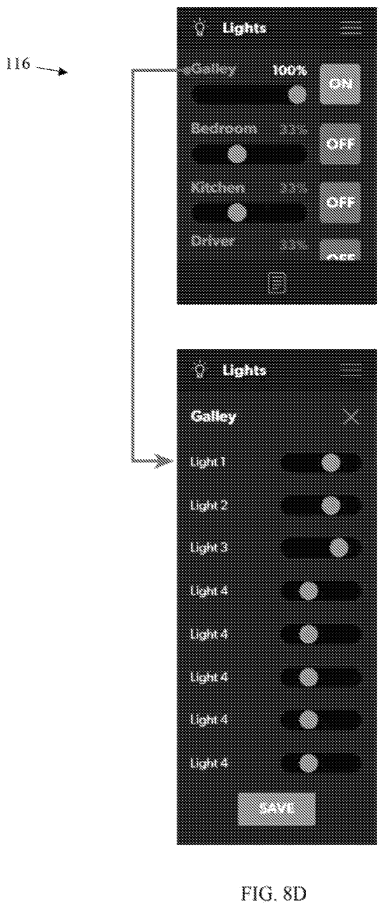

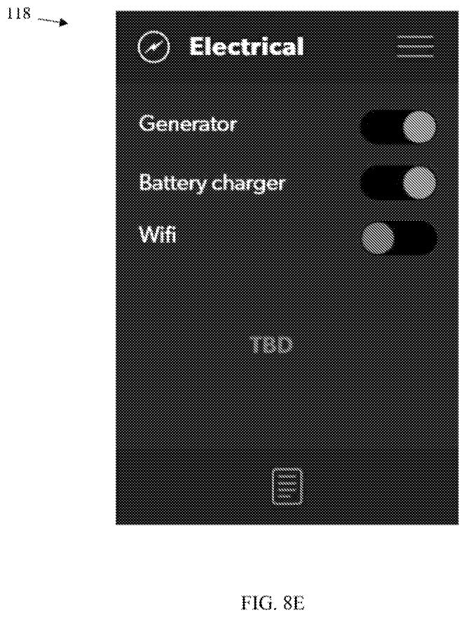

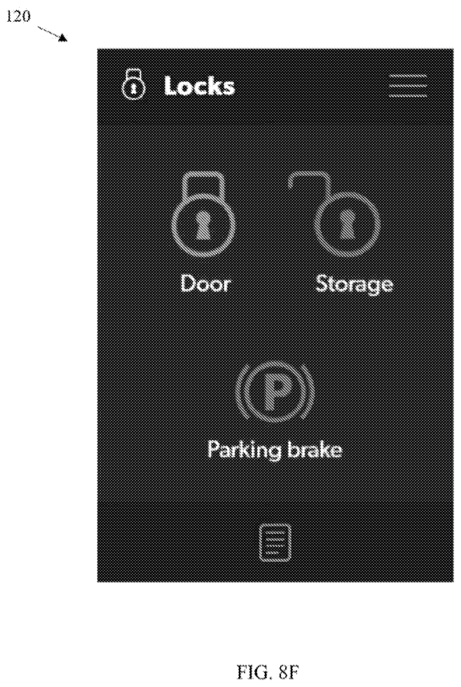

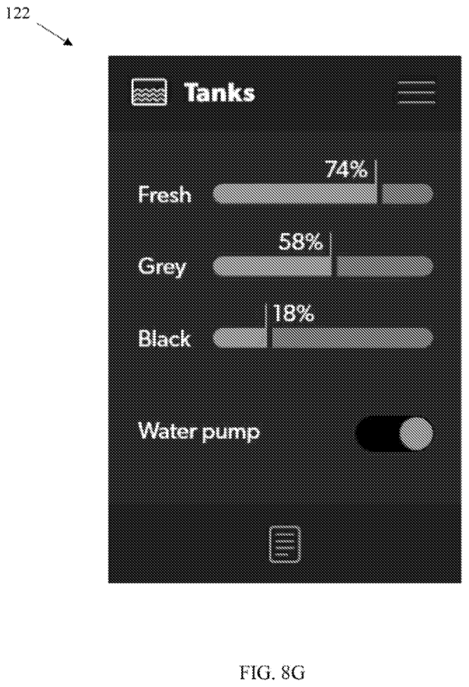

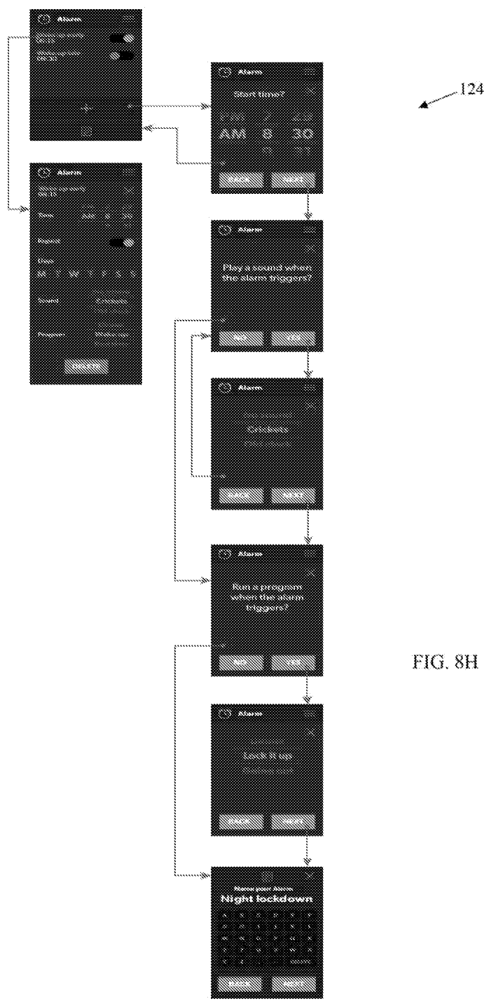

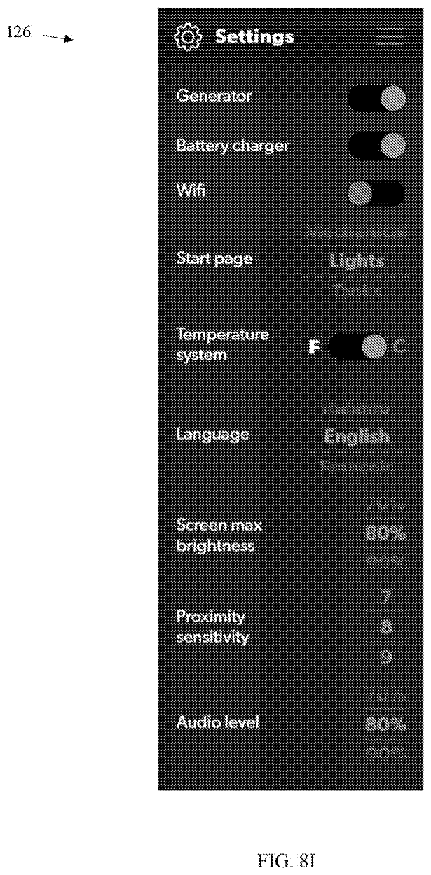

Referring now to FIG. 1, a schematic view of an RV 10 is depicted. The figure shows an RV 10 and a plurality of mechanical systems which are operably connected to the RV 10 and which render the camping activities more enjoyable. For example, the systems may include, but are not limited to, heating ventilation and air conditioning (HVAC) 12, an awning system 14, a lighting system 16, an electrical system 18, a door locking system 20, a fresh water and/or waste water system 22, an alarm system 24, and/or other systems 26. This list is not exhaustive and various others may be utilized. Each of these systems may comprise a set of controls which will be described further with regard to FIG. 8. However, for purposes of discussion, these controls allow for operation of the various systems of the RV 10 and allow for a user to operate the various functions of the RV 10 from one or more locations within the RV 10.

In accordance with the instant embodiments, the following brief description of the functions is provided with regard to some of the systems being controlled by a multiplex controller assembly 30.

The HVAC system 12 may include air conditioning equipment and heating devices which are illustratively, but not in a limiting manner, shown on the roof of the RV 10. The HVAC system 12 may additionally include ventilation device, such as a roof fan 13 which may be solely used to vent the RV 10, or may be used in combination with the HVAC to more quickly cool the RV 10, for example in the summer when the RV 10 has been sitting for some time in the sun and the cooling system has been off.

Additionally the RV 10 may include an awning system 14 which may include one or more awnings which create a shaded area adjacent to the RV 10 and/or over windows of the RV 10. The RV awning(s) system 14 may be roller tube or cassette type awnings, for non-limiting example. The awnings system 14 may be controlled from the multiplex controller assembly 30 for ease of extension or retraction from the interior of the RV 10. In some embodiments, additional awnings may be provided for individual windows for example.

Additionally, some RVs may comprise slide out portions to expand the interior size of the RV 10. Controls may be provided to adjust the position of the slide out (now shown).

In still additional embodiments, the RV 10 may include lighting 16, interior and/or exterior, which provides desired illumination. For example, the illumination may be along walls of the RV 10, on or about the awning, about the entry ways to the RV 10 or may be segregated by room within the RV 10. Lights may be added at any of various locations and power control of these may be provided by the multiplex controller assembly 30. Still further, it may be also desirable to provide additional control of lighting effects. For example, some lights may be able to be dimmed in addition to powered on and off. Further, some lights may be able to be color controlled, any of these being desirable to create a mood within or about the exterior of the RV 10.

Still further, the RV 10 may include one or more generators as a power or electrical system 18. For example, the electrical system may have a generator which can be started by control of the multiplex controller assembly 30. The multiplex controller assembly 30 may also include information on the status of the electrical system such as fuel level for the generator and/or charge levels for batteries in the RV 10. Or the assembly 30 may provide power usage levels for the systems onboard the RV 10. Further, the electrical system 18 may include the capability to detect and/or switch to shore power when detected.

The RV 10 may also comprise a water system 22 which may include multiple tanks. For example, the water system 22 may include, in some embodiments, at least one each of a fresh water supply tank 21, a gray water tank 23 and a black water tank 25. The water levels for many of these tanks may be provided to the user by the multiplex controller assembly 30. Still further, as will be described further, it may be desirable to provide some predictive information on tank levels to inform a user when the fresh water may be empty or when the gray and black water tanks may need to be emptied.

Still more systems may be controlled by the multiplex controller assembly 30. For example, in some embodiments, the locks and/or an alarm systems 20, 24 may be controlled.

Further, it may be desirable to provide combinations of functionality dependent upon the room the user is located in. For example, if a user is in a bathroom, it may be desirable to have control of a ventilation fan, lights and a water pump. In other locations, for example a bedroom, it may be desirable to control HVAC and lights at least to aid in sleeping, or additionally, to provide locking and alarm setting for security piece of mind. Further, the multiplex controller assembly 30 may also include a proximity sensor so that the screen may illuminate when a user moves close by the device. However, where such controller assembly 30 is placed near a bed it may be desirable to limit the illumination during night time hours when the user may roll or move in bed during sleep so that the illumination does not wake the user.

Also shown in the RV 10 are various multiplex controller assemblies 30 which are shown located in various locations of the RV 10. This is convenient for grouping controls, for the room where the assembly 30 is located. As mentioned previously, the controllers may have some desired control functions in a bathroom, different control functions in a bedroom, and still other desired functions in a galley for example. Still further, in some rooms, for example the galley, it may be desirable to have more functions available to the user. For example, it may be desirable to lock and alarm the RV 10 near the entry/exit door of the RV 10. Further, it may be desirable to have control function of the awning system 14 and the HVAC system 12. With a single multiplex controller assembly, this would require the need to scroll through multiple menus to get to the various control screens desired. The ability to multiplex the controllers allows for the different screens to be programed to the most desired functions so that the scrolling is not needed and so that the various functions may most easily be accessed by the user. Further, more functions may be provide by merely addition of controllers.

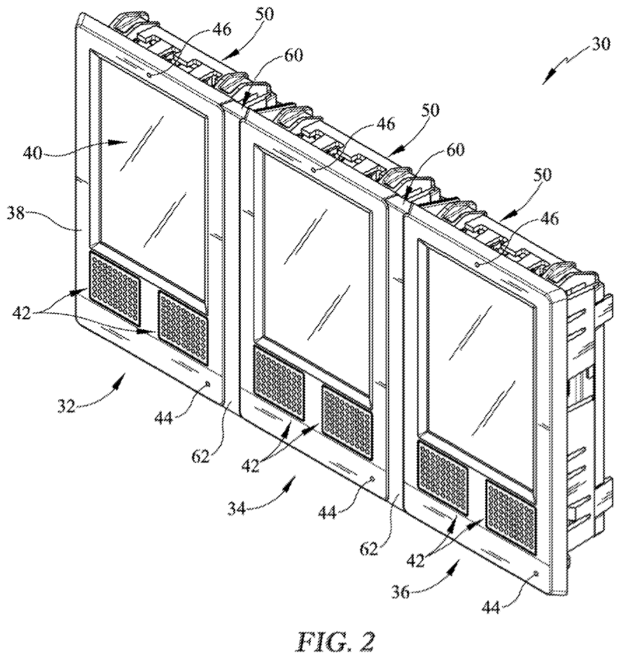

Referring to FIG. 2, the multiplex controller assembly 30 is depicted. The multiplex controller assembly 30 allows for control of the various systems shown and described in relative to FIG. 1 at a single location or by way of placing multiple of the multiplex controllers at differing locations within the RV 10. Each multiplex controller assembly 30 may comprise two or more controllers 32, 34, 36. In the instant embodiment, for non-limiting example, three controllers 32, 34, 36 are depicted as being connected together. Each controller 32, 34, 36 may comprise various structures which allow for numerous functionalities and control of the various systems shown in FIG. 1. For example, with reference to controller 32, each of the controller may include an optional bezel 38 which surrounds a display screen 40. Further however, it may be desirable to eliminate the bezel 38 where possible, in some embodiments. The bezel 38 may be formed of various structures including, but not limited to, injection molded plastics or other structures which have any of various desirable finishes, which may be aesthetically pleasing for a user.

The controller assembly 30 may have various electrical components either onboard or providing input. The controller may include a microcontroller or processor, memory, RV-C and Bluetooth and Wi-Fi communication standard, Air conditioning communication standard for example serial, audio amplifier and speaker or buzzer, a microphone, humidity and temperature sensor, ambient light or proximity sensor, real time clock, battery and holder, a touch screen display, a camera, a power supply, and other connections and connectors.

The display screen 40 may be defined by an liquid crystal display (LCD) screen, light emitting diode (LED) screen, an organic light-emitting diode (OLED), or other screens which may provide a display of menus and/or control functions. Additionally, these screens 40 may be touch sensitive in order to allow user input at each of the display screens 40 and make desirable selections for control functionality of the systems of the RV 10. The display screen 40 may be of various sizes and is not limited to any specific size or shape.

Each of the controllers 32, 34, 36 may also comprise one or more speakers 42 and may further comprise a microphone 44 which may be located in the bezel 38 for use of the controller 32, 34, 36 as an intercom or to stream audio files for example or to sound notifications or alarms. The controllers 32, 34, 36 may further comprise a camera 46 in some embodiments. The camera 46 may be used to monitor an area, for example for security purposes. The camera 46 may alternatively be utilized to have a video intercom or alternatively video conferencing capability between the controllers 32, 34, 36 which may be spaced about in the RV 10 or alternatively, be used with internet accessible systems to provide video conferencing capability to a party who is at a location spaced away from the RV 10 where the multiplex controller 30 is located.

The controllers 32, 34, 36 further comprise at least one frame 50 which generally defines a rear housing for the controllers. The frame 50 may define a volume wherein the electronic components of the controllers are disposed and which provide the functionality for the controllers 32, 34, 36 individually and collectively. For example, the frame 50 may also include some mounting hardware for mounting of the frame 50 and the entire controller 32, 34, 36, individually or collectively, to a substrate within the RV 10. Alternatively, a separate mounting hardware may be provided, to which the frame 50 may be easily connected. In some embodiments, the frame 50 may be formed of one structure or two or more structures in order to surround the electrical components.

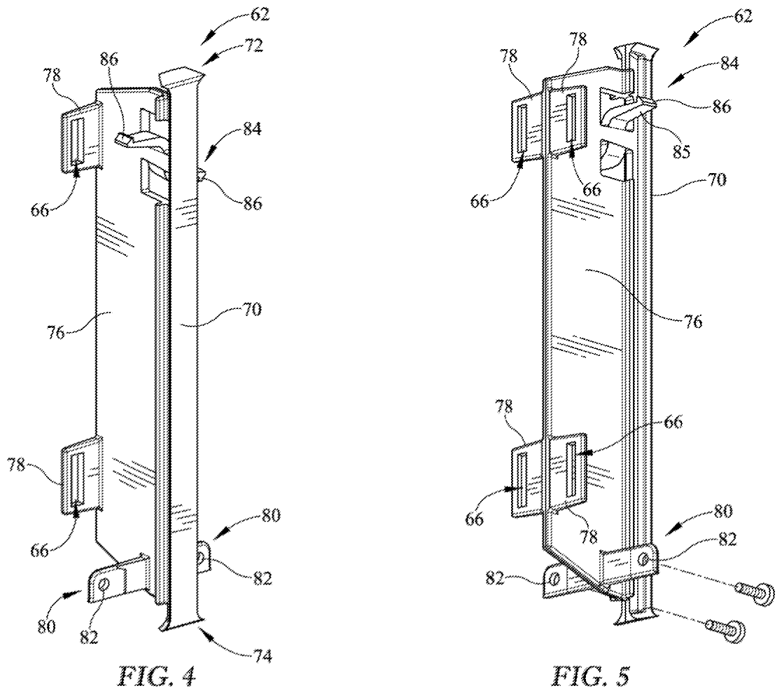

Also shown in the instant embodiment, are connecters 60 which are extended between the controllers 32, 34 and 34, 36. The number of connectors 60 is dependent upon the number of controllers being utilized to define the multiplex controller. The connectors 60 may extend directly from the frames 50 in some embodiments or may be separate parts which are disposed between the controllers 32, 34, 36 in order to provide the connecting functionality. As depicted in FIG. 4, the connectors 60 are defined by rib connectors 62 in some embodiments. Further, while the connectors 60 are shown to allow for linear horizontal connections, it should be understood that further embodiments may be provided in the vertical direction as well or may be provided for a combination of vertical and horizontal to define rows and columns.

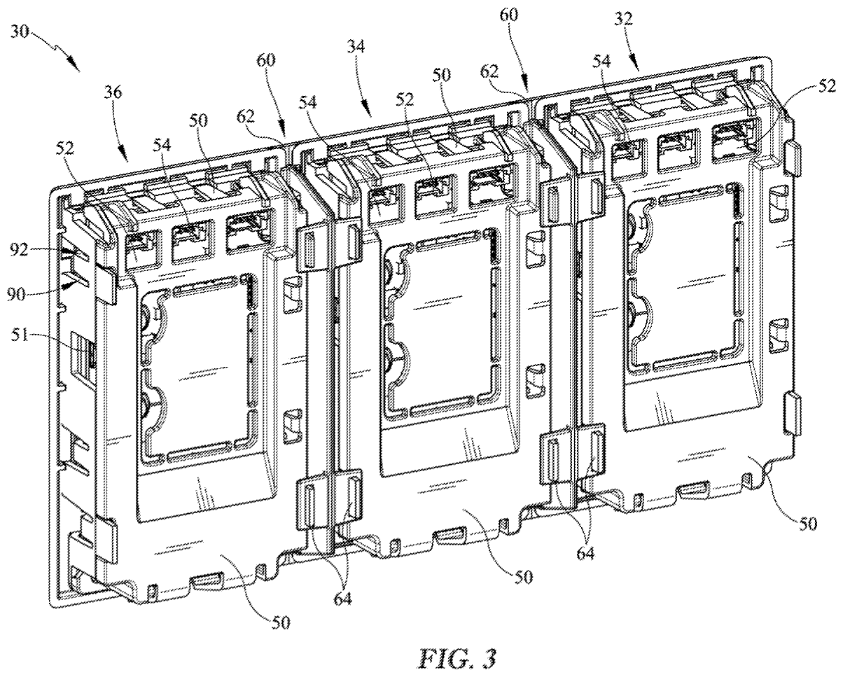

With reference now to FIG. 3, a rear perspective view of the multiplex controller assembly 30. In this embodiment, the multiplex controller assembly 30 still has three controllers 32, 34, 36. However, two or more controllers may be utilized to define the assembly 30. As depicted in the instant view, within the frames 50, are electronic components which dictate the operation of each of the controllers 32, 34, 36, individually and in some embodiments, which may be in communication to provide control of the two or more controllers when they are connected to define the multiplex controller assembly 30. The frames 50 have a plurality of sides, some of which have openings, for example, to allow for heat ventilation and further which may also allow for access to the interior of the controllers 32, 34, 36. Near the upper portions of the instant frames 50 are windows 52 wherein at least one printed circuit board (PCB) 54 is shown within the controllers 32, 34, 36. The PCBs 54 may comprise electronics thereon and coding embedded therein in order to provide desirable display menus as well as capability of control functions for the various systems of the RV 10. Still further, the PCB may include thereon, or connected thereto, at least one communication module.

Further, the controller assembly 30 may be in communication, wired or wirelessly, with a plurality of sensors onboard the RV systems. Further the controller assembly 30 may be in communication with smart devices and/or with the cloud to databases which may provide input to the controller assembly 30 such as weather databases based on GPS coordinates and the like.

The frame 50 may also comprise functional windows 51 for connection of diagnostic and/or programming connections such as USB, micro USB, data port, or other types of electrical connections for power and/or communication to, for example, provide programming and/or updates to the printed circuit board and coding thereon. Additionally, various openings 90, 92 may be provided in the frame 50 to receive connectors 60 of adjacent controllers. Alternatively, or additionally, the frames 50 may further comprise various connectors which extend from a first controller to an adjacent second controller and may engage, for example, in one of the locking openings 90, 92 within the frame 50 of an adjacent controller. While some embodiments may provide connectors which extend from and/or receive from one controller, for example controller 32 to adjacent controller 34, other embodiments may be provided which utilize a connector which is not integrally formed into the frame 50 but instead is a separate part, which may be added between two controllers 32, 34, or 34, 36, for example.

Further, while the controllers 32, 34, 36 are all shown in a linear arrangement, other connectors may be also provided so that the controllers may be arranged vertically or in pairs of rows or columns instead of or in addition to the single row that is depicted in the instant embodiments. The multiplex controller assembly 30 may be expanded in various manners by direct connection of the controllers or by use of the connectors 60.

With reference still to FIG. 3, the connectors 60 disposed between the controllers 32, 34, and 34, 36 are distinct parts which are connected to each of the adjacent controllers in order to provide mechanical and/or electrical connection. The connectors 60 are provided to connect adjacent controllers 32, 34, 36 and may be a distinct part or may be formed in the frames 50. With brief reference to FIG. 2, the connectors 60 are shown, according to one illustrative embodiment, as rib connectors 60 having a rib structure 62 extending vertically between the bezels 38 (FIG. 2) of adjacent controllers 32, 34, 36. At the rear of the controllers 32, 34, 36, extending from the frames 50 are tabs or latches. Additionally, or alternatively, the connectors 60 may include apertures 66 which are engaged by the tabs or latches 64. These parts of tabs 64 and apertures 66 may also be reversed so that the apertures 66 are located on the frames 50 and either extend from an adjacent frame 50 or may be utilized on a distinct connector part which engages the frames 50. Thus, various combinations of these male and female parts may be utilized. It may be desirable in some embodiments to limit movement in various dimensions with the various connections.

The frame 50 may be formed so that the frame or frames 50 can be attached to a wall or substrate and subsequently the remainder of the controller, for example, including the display screen 40, bezel 38, and a printed circuit board 54 may be snapped into place or otherwise fastened to the frames 50, once the frames are in position on the substrate. Alternatively, the frame 50 may be connected to an additional piece of hardware which connects to a wall or substrate.

Referring now to FIGS. 4 and 5, two perspective views of the rib connectors 62 are depicted corresponding to one embodiment of the connectors which may be used to connect adjacent controllers. Referring first to FIG. 4, a front perspective view is shown. The rib connector 62 includes a front rib 70, which extends vertically between an adjacent pair of controllers 34, 36, (FIG. 2) for example. At the top and bottom of the rib 70 may be a decorative flange 72, 74 which provides a finishing appearance adjacent to the bezels 38 of each of the controllers 32, 34, 36. Extending from the rear of the rib 70 is a web 76. The web 76 provides spacing which in some embodiments corresponds to a rear dimension of the frame 50 (FIG. 1) and generally also provides additional stiffness or structural support for the rib 70. The web 76 is shown as a generally trapezoidal shape but may take various forms with more or less number of edges to define the shape of the web 76. The depth of the web 76 positions these flanges 78 accordingly to receive the tabs 64 (FIG. 3). At rearward ends of the web 76, along the edge are the flanges 78 which extend laterally from surfaces of the web 76. Within these flanges 78 are apertures 66 which receive the tabs 64 (FIG. 3) extending from the frame 50. Further, however, tabs may be utilized on the connectors 62 and opposite flanges and apertures may also be used on the frames 50. In the instant embodiment, the flanges 78 extend generally perpendicular from the web surface 76. However, these flanges 78 may also be disposed at an angle depending upon the positioning of the cooperating male structure on the frame 50 or alternatively the male and female nature of the connecting structures may be reversed. The web 76 has a dimension which spaces the flanges 78 so that they clear the rear surfaces of the frames 50 and are able to receive the tabs 64.

With reference additionally to FIG. 5, the arrangement of the flanges 78 is shown in the rear perspective view. The flanges 78 may extend from both surfaces of the web 76. Further, while the flanges 78 are shown to extend laterally at the same general elevation, one skilled in the art may realize that the flanges 78 may be adjusted so that they extend outwardly at differing elevations if desirable. Accordingly, the depicted relationship of pairs of flanges 78 is not to be considered limiting.

Additionally, shown extending from the forward end of the web 76 and closer to the rib 70, the fastener flanges 80 are positioned at a location to cooperate with apertures which may be located in the frames 50 of adjacent controllers 32, 34, 36. The flanges 80 have fastener apertures 82 so that a fastener may pass through the rib connector 62 and through into the frames 50. Similar to the flanges 78, the flanges 80 are shown extending from opposite sides of the web 76 at equivalent elevations. However, depending on the corresponding construction of the frame 50, the vertical locations of these flanges 80 may differ along each side of the web 76 or the pairs of flanges 80 may be disposed at different elevations from that which is depicted.

Near the upper end of the web 76 is a latch 84. The latch 84 is generally “S” shaped or may be considered “Z” shaped. Other shapes may be utilized, however, each end of the latch 84 may have a catch 86. The latch 84 may comprise arms 85 that extend laterally to end in positions where the catches 86 are disposed. Each of the catches 86 may be inserted into apertures of the frames 50 and each catch 86 may engage in a positive locking manner some portion or structure of or within the frame 50 so as to lock to rib connector 62 in position relative to each of a pair adjacent controllers 32, 34, 36.

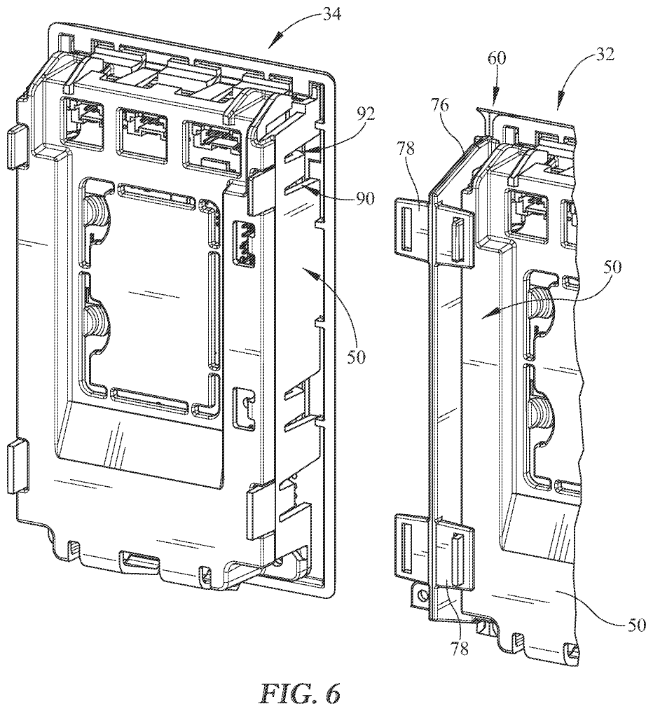

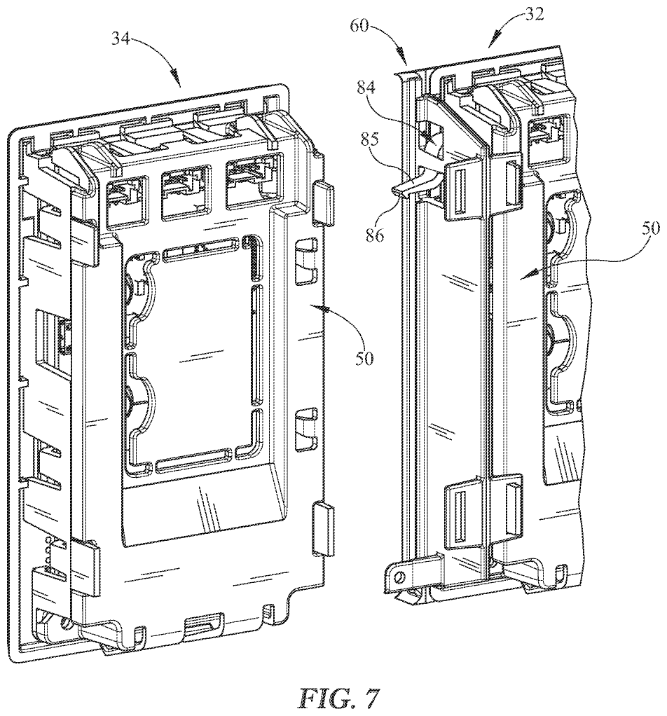

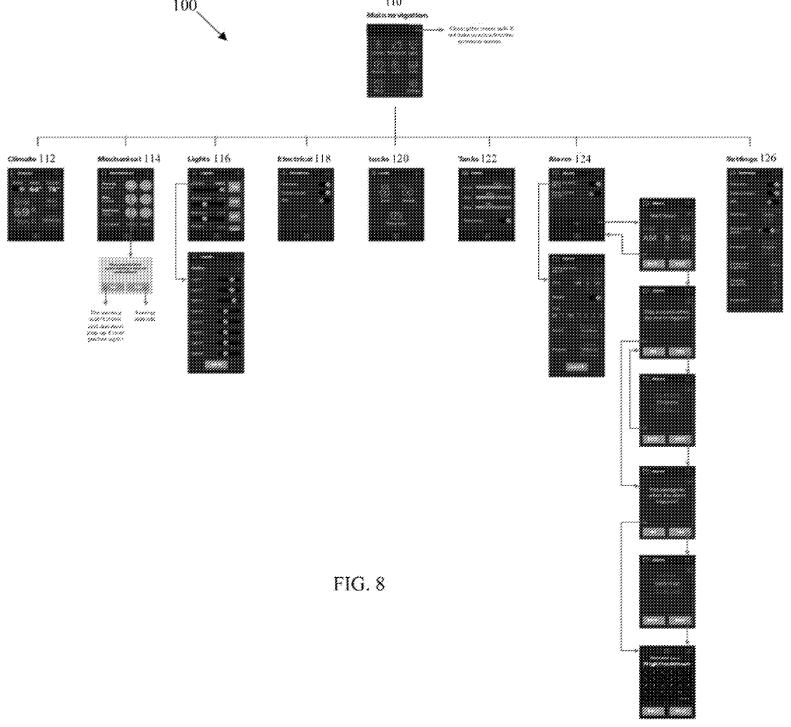

Referring now to FIGS. 6 and 7, a multiplex controller assembly 30 is depicted wherein one connector 60 is engaging the controller 32 and the second controller 34 is exploded or spaced apart from the connector 60. In the close up view, the flanges 78 on one side of the web 76 are engaging the frame 50 of the controller 32. One arm 85 of the latch 84 is also extending into the frame 50 of controller 32 and the catch 86 (FIGS. 4, 5) is engaging an internal portion of the frame 50 or other structure within the controller 32. In order to connect the second controller 34, the rear tabs 64 may be disposed in the open apertures 66. Once inserted, the controller 34 may be pivoted toward the connector 60 so that the catch 86 is inserted into the frame 50 of controller 34.

As may be gleaned from the view of FIG. 6, the flanges 78, including the tabs 64 extending there through, locate the connector 60 relative to the connected controller 32 and likewise, limit movement of the controller 32 in a lateral or side to side direction. Additionally, the catch 86 inside the frame 50 of controller 32 also locks the structure together inhibiting lateral movement. The flanges 78 also inhibit vertical motion of the controller 32, relative to the connector 60, or vice versa.

As shown in the frame 50 of the controller 34, a gap or opening 90 is provided for the opposite half of the latch 84 and provides an edge at which the catch 86 (FIG. 7) may grasp the frame 50 of the controller 34. Likewise, an upper opening 92 may be located on the frame 50 of the controller 32 in order to receive the opposite side of the latch 84. While these structures are depicted herein, other embodiments may be utilized.

In some embodiments, the connector 60 may comprise one or more connectors which are formed integrally with the frames 50 so that the controllers 32, 34, for example, may be snapped together. Further, other embodiments may be provided wherein different locations and/or shapes of the latches, tabs and/or apertures may be provided to ease the connection process or provide an alternative stable connection between controllers 32, 34, 36. Further, as previously mentioned, while the instant controllers 32, 34, 36 are shown connecting in a linear and horizontal fashion, other connectors may be provided which also allow for positioning of a controller in a vertical fashion and/or horizontal so that two or more rows of controllers may be utilized.

Referring now to FIG. 8, a plurality of screen shots are provided of an illustrative control system 100 which generally define a tree for control purposes. At the top of FIG. 8 is a home navigation screen 110 which comprises various functionalities from which a user may select. The selections may include, for non-limiting example, climate control, mechanical control, for example awning control and positioning, lighting control, alarms, and various other controls which will be discussed further herein. Once a selection is made at the home navigation screen 110, the display changes to one of the function specific selected control screens.

As previously discussed, in moving from control of, for example, climate control, to control of various alarms, be they reminder alarms or security type alarms, it may require a user to scroll through multiple screens in order to back out of one set of menus and move into a second set of menus. One advantage of the instant embodiments provides that when multiple controllers are multiplexed, the user may utilize one of the controllers, for example controller 32, to control one or more series of functionalities and may utilize a second controller 34, for example, to control a second or more set of functions to reduce or eliminate this need for scrolling through a large number of screens.

From the home navigation screen 110 (shown in FIG. 8A), a plurality of system module screens may be accessed. In the illustrative example, and without limitation, additional screens include control for a climate control screen 112 (shown in FIG. 8B), a mechanical control screen 114 and 114A (shown in FIG. 8C), for example which may relate to awning control, a light control screen 116 and 116A (shown in FIG. 8D) which may be utilized to control lighting both in the interior, exterior, and on the awning or about other areas of the RV. Additional screens may include, but are not limited to, an electrical screen 118 (shown in FIG. 8E) which may give information regarding control of one or more generators battery charging/condition on the RV, a lock control screen 120 (shown in FIG. 8F) which may lock the RV and/or may be utilized to lock the control system of the multiplex controller assembly. Further control may include a control screen 122 (shown in FIG. 8G) for tank status which may include levels for the fresh water tanks, a level of the black water tank, and a level for the gray water tanks. Still further, an alarm screen 124 and 124A-G (shown in FIG. 8H) may be set up to provide alarms for either reminders or for security systems or both. Additionally, a home screen for settings 126 (shown in FIG. 8I) may also be provided which relate to various setting necessary for use of the multiplex controller assembly.

Still further, and with brief reference to FIG. 1, a wireless connection may be provided, for non-limiting example by Bluetooth connection, which allows for use of an individual controller or the multiplex controller assembly 30 with a smart device, such as a phone, tablet, laptop, smart watch, or the like. Accordingly, any of the control screens of the controller 32 (for example) may be emulated on the smart device for making menu selections to control any of various functionalities. Further however, other communication standards may be used. For example, as an alternative, or in addition to, Bluetooth, the wireless connection may be via a Wi-Fi protocol. Still further, other communication protocols may be used alternatively, or in addition to, that which is shown.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the invent of embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms. The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

The foregoing description of methods and embodiments has been presented for purposes of illustration. It is not intended to be exhaustive or to limit the invention to the precise steps and/or forms disclosed, and obviously many modifications and variations are possible in light of the above teaching. It is intended that the scope of the invention and all equivalents be defined by the claims appended hereto.

1. A multiplex controller assembly, comprising:
a first controller having:
a display;
a speaker;
a frame having one of a connector or opening for said connector, a second controller having:
a second display;
a second speaker;
a second frame, which is connectable to said first frame in order to provide the multiplex controller assembly.

2. The multiplex controller assembly of claim 1 further comprising a connector disposed between said first controller and said second controller.

3. The multiplex controller assembly of claim 2, further comprising at least one electrical connector.

4. The multiplex controller assembly of claim 3 said connector being at least one mechanical connector.

5. The multiplex controller assembly of claim 4, said at least one mechanical connector having a first connector which inhibits motion in one direction.

6. The multiplex controller assembly of claim 5, further comprising a second connector which inhibits motion in a second direction.

7. The multiplex controller assembly of claim 1 further comprising a camera on each of said first and second controllers.

8. The multiplex controller assembly of claim 1 wherein the first and second controllers are horizontally aligned.

9. The multiplex controller assembly of claim 1 wherein the first and second controllers are vertically aligned.

10. The multiplex controller assembly of claim 1 wherein said connector is a distinct part formed separate of said frame.

11. The multiplex controller assembly of claim 1 wherein said connector is formed integrally with said frame.

12. The multiplex controller assembly of claim 1 wherein said first controller controls a first system and said second controller controls a second system.
